(19) United States
(12) Patent Application Publication
(10) Pub. No.: US 2026/0040497 A1
(43) Pub. Date: Feb. 5, 2026

(54) BRACKET APPARATUS FOR AMBIENT TEMPERATURE REGULATION OF NETWORK INTERFACE CARDS

(71) Applicant: Dell Products L.P., Round Rock, TX (US)

(72) Inventors: Jason Christopher Rock, Austin, TX (US); Shree Rathinasamy, Georgetown, TX (US)

(21) Appl. No.: 18/794,450

(22) Filed: Aug. 5, 2024

(51) Int. Cl. H05K 7/20

(52) U.S. Cl. CPC H05K 7/20554; H05K 7/207

(57) ABSTRACT

A bracket apparatus for ambient temperature regulation of network interface cards. The bracket apparatus includes: a static outer bracket, including: a plurality of outer bracket vents; and a moveable inner bracket capable of sliding vertically against the static outer bracket, and including: a plurality of inner bracket vents, which: permits a passage of cold-side airflow when aligned with the plurality of outer bracket vents, and impedes the passage of the cold-side airflow when misaligned with the plurality of outer bracket vents.

### BACKGROUND

Unlike datacenters, where equipment is placed in temperature-controlled settings, edge or telecom equipment more commonly reside in environments subject to varying temperatures. In recent years, edge/telecom equipment have begun to adopt peripheral component interconnect express (PCIe) card electro-mechanical (CEM) network adapters (or network interface cards) to implement communications over networks. The computer processor(s), of/on said network interface cards, however, is/are often operationally rated for temperatures above a certain threshold.

### SUMMARY

In general, in one aspect, embodiments described herein relate to a bracket apparatus for ambient temperature regulation of network interface cards. The bracket apparatus includes: a static outer bracket, including: a plurality of outer bracket vents; and a moveable inner bracket capable of sliding vertically against the static outer bracket, and including: a plurality of inner bracket vents, which: permits a passage of cold-side airflow when aligned with the plurality of outer bracket vents, and impedes the passage of the cold-side airflow when misaligned with the plurality of outer bracket vents.

In general, in one aspect, embodiments described herein relate to a network interface card. The network interface card includes: a computer processor; at least one small form-factor pluggable (SFP) port operatively connected to the computer processor; and a bracket apparatus fitted to, and for ambient temperature regulation of, the network interface card. The bracket apparatus includes: a static outer bracket, including: a plurality of outer bracket vents; and a moveable inner bracket capable of sliding vertically against the static outer bracket, and including: a plurality of inner bracket vents, which: permits a passage of cold-side airflow when aligned with the plurality of outer bracket vents, and impedes the passage of the cold-side airflow when misaligned with the plurality of outer bracket vents.

In general, in one aspect, embodiments described herein relate to a computing system. The computing system includes: a chassis formed from multiple panels fastened together. The multiple panels including a panel exposed to a cold-side airflow. The chassis enclosing: a motherboard; a computer processor incorporated into the motherboard; and a network interface card operatively connected to the computer processor. The network interface card includes: a second computer processor; at least one small form-factor pluggable (SFP) port operatively connected to the second computer processor; and a bracket apparatus fitted to, and for ambient temperature regulation of, the network interface card. The bracket apparatus includes: a static outer bracket, including: a plurality of outer bracket vents; and a moveable inner bracket capable of sliding vertically against the static outer bracket, and including: a plurality of inner bracket vents, which: permits a passage of the cold-side airflow when aligned with the plurality of outer bracket vents, and impedes the passage of the cold-side airflow when misaligned with the plurality of outer bracket vents.

Other aspects of the embodiments described herein will be apparent from the following description and the appended claims.

### BRIEF DESCRIPTION OF DRAWINGS

Certain embodiments described herein will be described with reference to the accompanying drawings. However, the accompanying drawings illustrate only certain aspects or implementations of the embodiments by way of example and are not meant to limit the scope of the claims.

FIG. 1 shows an edge or telecom appliance in accordance with one or more embodiments described herein.

FIG. 2A shows a network interface card in accordance with one or more embodiments described herein.

FIG. 2B shows an actuator controller in accordance with one or more embodiments described herein.

FIG. 2C shows an outer bracket in accordance with one or more embodiments described herein.

FIG. 2D shows an inner bracket in accordance with one or more embodiments described herein.

FIG. 2E shows an open-vents configuration of an assembled bracket apparatus in accordance with one or more embodiments described herein.

FIG. 2F shows a closed-vents configuration of an assembled bracket apparatus in accordance with one or more embodiments described herein.

FIG. 3 shows a flowchart outlining a method for ambient temperature regulation of a network interface card in accordance with one or more embodiments described herein.

### DETAILED DESCRIPTION

Specific embodiments will now be described with reference to the accompanying figures.

In the below description, numerous details are set forth as examples of embodiments described herein. It will be understood by those skilled in the art (who also have the benefit of this Detailed Description) that one or more embodiments of embodiments described herein may be practiced without these specific details, and that numerous variations or modifications may be possible without departing from the scope of the embodiments described herein. Certain details known to those of ordinary skill in the art may be omitted to avoid obscuring the description.

In the below description of the figures, any component described with regard to a figure, in various embodiments described herein, may be equivalent to one or more like-named components described with regard to any other figure. For brevity, descriptions of these components may not be repeated with regard to each figure. Thus, each and every embodiment of the components of each figure is incorporated by reference and assumed to be optionally present within every other figure having one or more like-named components. Additionally, in accordance with various embodiments described herein, any description of the components of a figure is to be interpreted as an optional embodiment, which may be implemented in addition to, in conjunction with, or in place of the embodiments described with regard to a corresponding like-named component in any other figure.

Throughout the application, ordinal numbers (e.g., first, second, third, etc.) may be used as an adjective for an element (i.e., any noun in the application). The use of ordinal numbers is not to imply or create any particular ordering of the elements, nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Throughout this application, elements of figures may be labeled as A to N. As used herein, the aforementioned labeling means that the element may include any number of items and does not require that the element include the same number of elements as any other item labeled as A to N. For example, a data structure may include a first element labeled as A and a second element labeled as N. This labeling convention means that the data structure may include any number of the elements. A second data structure, also labeled as A to N, may also include any number of elements. The number of elements of the first data structure and the number of elements of the second data structure may be the same or different.

As used herein, the phrase operatively connected, or operative connection, means that there exists between elements/components/devices a direct or indirect connection that allows the elements to interact with one another in some way. For example, the phrase ‘operatively connected’ may refer to any direct (e.g., wired directly between two devices or components) or indirect (e.g., wired and/or wireless connections between any number of devices or components connecting the operatively connected devices) connection. Thus, any path through which information may travel may be considered an operative connection.

In general, embodiments described herein relate to a bracket apparatus for ambient temperature regulation of network interface cards. Particularly, unlike datacenters, where equipment is placed in temperature-controlled settings, edge or telecom equipment more commonly reside in environments subject to varying temperatures. In recent years, edge/telecom equipment have begun to adopt peripheral component interconnect express (PCIe) card electro-mechanical (CEM) network adapters (or network interface cards) to implement communications over networks. The computer processor(s), of/on said network interface cards, however, is/are often operationally rated for temperatures above a certain threshold. That is, if the ambient temperature of the network interface card falls below said threshold, then the computer processor of/on the network interface card ceases to operate.

Embodiments described herein, therefore, propose a solution directed to mitigating exposure of network interface cards to temperatures below their operational rating using a novel bracket apparatus. Said bracket apparatus includes a (static) outer bracket, a (sliding) inner bracket configured to move vertically upwards and downwards relative to the outer bracket, and an actuator effecting movement of the inner bracket. The outer and inner brackets both include respective bracket vents (or openings) through which (cooled) air may or may not pervade through to the printed circuit board of any network interface card fitted with said bracket apparatus.

Further, coupled or operatively connected to the actuator is an actuator controller integrated into the network interface card, which is configured to sense the ambient temperature surrounding the network interface card and activate or deactivate the actuator based on a comparison between said sensed ambient temperature and a threshold temperature indicating the operational temperature rating for the computer processor of/on the network interface card. When the sensed ambient temperature equals or exceeds the threshold temperature, the actuator is deactivated, thereby moving the inner bracket (relative to the outer bracket) such that an alignment, of the inner bracket vents and outer bracket vents, results. Said alignment enables exposure of the network interface card to any cold airflow. On the other hand, when the sensed ambient temperature falls below the threshold temperature, the actuator is activated, thereby moving the inner bracket (relative to the outer bracket) such that a misalignment, of the inner bracket vents and the outer bracket vents, instead results. Said misalignment prevents exposure of the network interface card to any cold airflow.

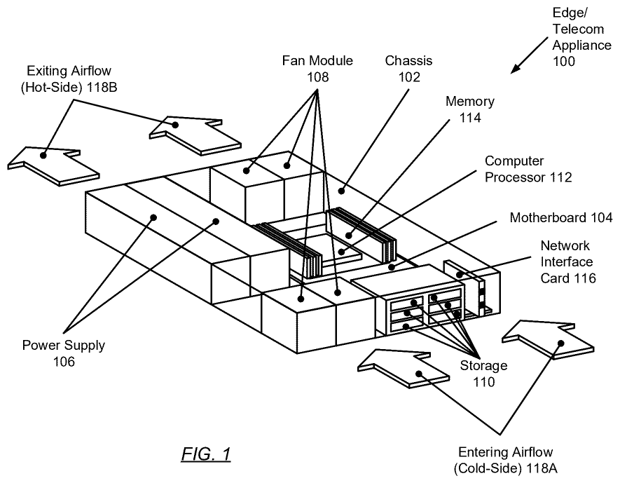

FIG. 1 shows an edge or telecom appliance in accordance with one or more embodiments described herein. An edge appliance represents any distributed computing platform owned and operated by a network/telecom provider, however, deployed near or within a premise of a customer. A telecom appliance, on the other hand, represents any communications platform owned and operated by, as well as deployed within the premise of, the network/telecom provider. The edge/telecom appliance (100) includes a chassis (102), a motherboard (104), one or more power supplies (106), one or more fan modules (108), storage (110), a computer processor (112), memory (114), and one or more network interface cards (116). Each of these edge/telecom appliance (100) components is described below.

In one or many embodiment(s) described herein, the chassis (102) represents, and thus serves, as a structural frame or housing within which the other above-mentioned components of the edge/telecom appliance (100) may be enclosed and/or to which one or more of said other above-mentioned components may be affixed or mounted. The chassis (102) may be assembled from multiple panels (not shown) that may be fastened together using any number and any form of mechanical fasteners (not shown)—e.g., screws, bolts, latches, rivets, etc. Further, the chassis (102) may be constructed of lightweight, yet rigid and durable materials such as, for example, steel, aluminum, plastics, carbon fiber, composites, or any combination thereof.

In one or many embodiment(s) described herein, the motherboard (104) represents a (main) physical printed circuit board (PCB) at least configured to interconnect, facilitate communications amongst, and distribute power to one or more of: the power supply/supplies (106), the fan module(s) (108), the storage (110), the computer processor (112), the memory (114), and the network interface card(s) (116). One of ordinary skill, however, will appreciate that the motherboard (104) may perform other functionalities without departing from the scope of the embodiments described herein.

In one or many embodiment(s) described herein, any power supply (106) represents a physical device at least configured to provide operational power to one or more other edge/telecom appliance (100) components (excluding the chassis (102)). To that extent, any power supply (106) includes functionality to convert or step-down alternating current (AC) high-voltage from an AC electricity source (e.g., wall socket/outlet, distribution transformer, etc.) to one or more direct current (DC) low-voltages required and regulated for stable operation of one or more of said other edge/telecom appliance (100) components. Furthermore, any power supply (106) includes circuitry (e.g., rectifiers, transformers, voltage dividers, voltage regulators, etc.) necessary to perform any AC/DC conversion.

In one or many embodiment(s) described herein, any fan module (108) represents a physical device at least configured to provide active cooling to one or more other edge/telecom appliance (100) components. Active cooling refers to a heat-reducing framework that consumes energy (e.g., electrical power) in order to implement proper heat transfer and airflow circulation. To that extent, any fan module (108) includes functionality to: draw in cool air (e.g., a cold-side entering airflow (118A)) from the outside surroundings, and into a cool-side end/panel, of the edge/telecom appliance (100); move said cool air over/across any one or more internal components of the edge/telecom appliance (100), which thereby absorbs at least a portion of any heat generated by said internal component(s) to become hot air; and expel said hot air (e.g., a hot-side exiting airflow (118B)) from a hot-side end/panel (opposite the cool-side end/panel), and into the outside surroundings, of the edge/telecom appliance (100).

In one or many embodiment(s) described herein, the storage (110) represents any number of non-transitory computer readable storage mediums at least configured for the storage of various forms of computer readable information (e.g., structured and/or unstructured data) in whole or in part, and temporarily or permanently. Said non-transitory computer readable storage mediums may include: one or more magnetic storage devices (e.g., hard disk drives (HDDs)), one or more solid-state storage devices (e.g., solid-state drives (SDDs)), or any combination thereof.

In one or many embodiment(s) described herein, the computer processor (112) represents an integrated circuit configured to process computer readable instructions. Said computer readable instructions may govern a behavior, or implement any specified functionalities, of the edge/telecom appliance (100). Further, said computer processor (112), for example, may encompass one or more cores or micro-cores of a central processing unit (CPU).

In one or many embodiment(s) described herein, the memory (114) represents any number of integrated circuits at least configured for short-term and/or long-term storage of data and computer readable instructions that may be quickly accessed by the computer processor (112). Said integrated circuits include volatile memory (e.g., random access memory (RAM)), non-volatile memory (e.g., read only memory (ROM)), or any combination thereof.

In one or many embodiment(s) described herein, any network interface card (NIC) (116) represents an integrated circuit at least configured for data transmission and reception over one or more networks (e.g., local area networks (LANs), wide area networks (WANs) such as the Internet, mobile networks, etc.).

In one or many embodiment(s) described herein, at least one network interface card (116), within the edge/telecom appliance (100), is positioned such that a (cold-side) entering airflow (118A), when traversing the edge/telecom appliance (100) via the airflow manipulation of any fan module(s) (108) therein, reaches or encounters the at least one network interface card (116) prior to reaching/encountering the computer processor (112). That is, the at least one network interface card (116) may be: disposed between the computer processor (112) and a cool-side end/panel (not shown) of the edge/telecom appliance (100); and mounted via mounting hardware (e.g., an expansion slot bracket) to said cool-side end/panel.

While FIG. 1 shows a configuration of components and/or subcomponents, other edge/telecom appliance (100) configurations may be used without departing from the scope of the embodiments described herein.

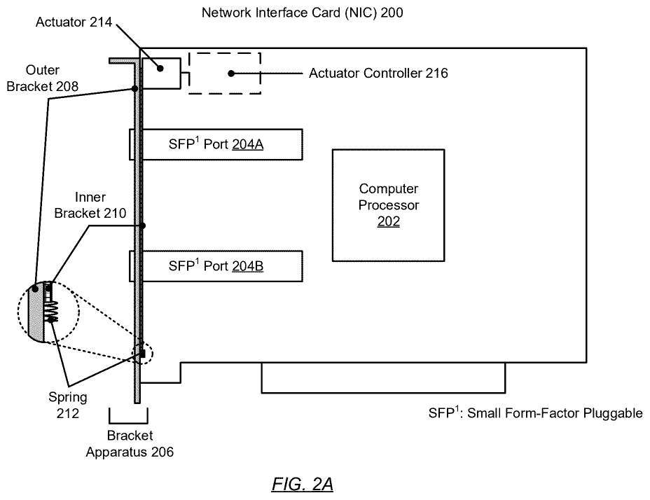

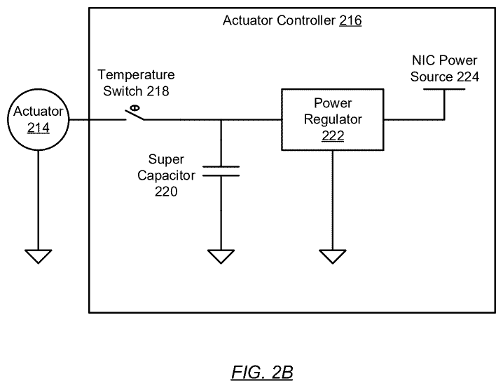

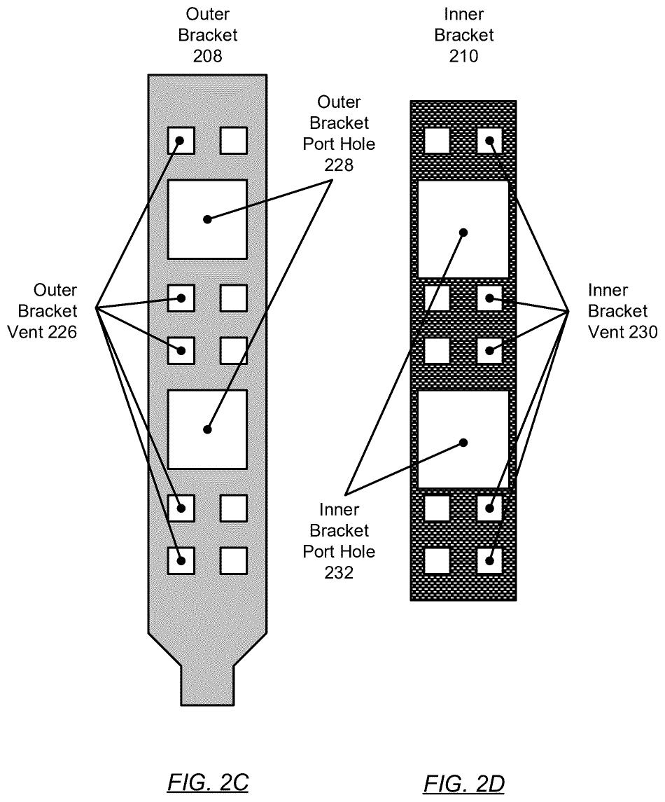

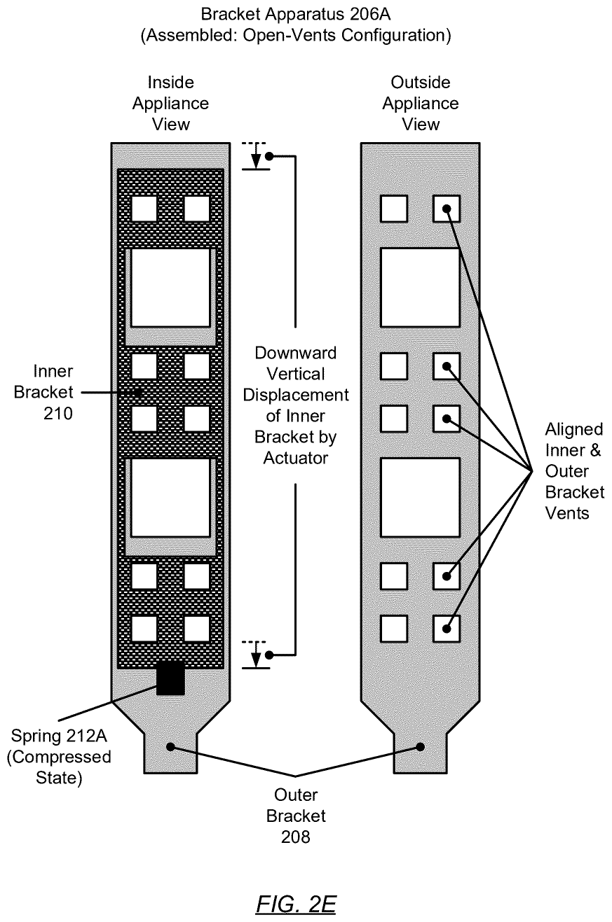

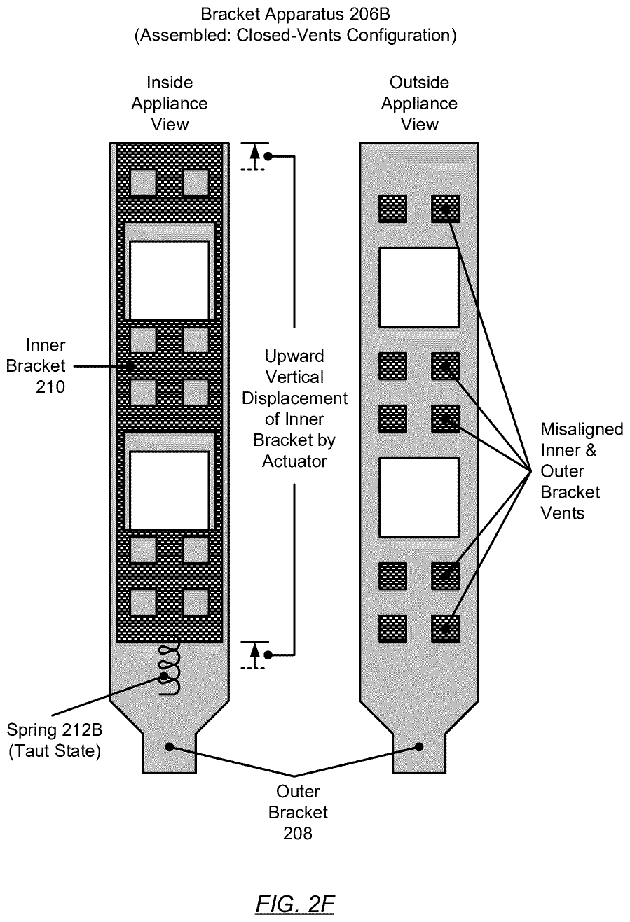

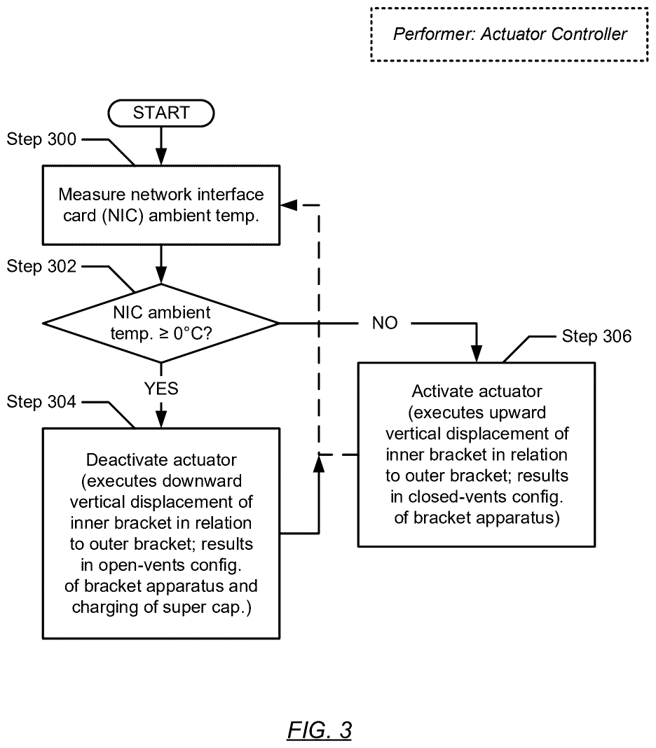

FIG. 2A shows a network interface card in accordance with one or more embodiments described herein. The network interface card (200) resembles any of the at least one network interface cards (see e.g., 116, FIG. 1) positioned within an edge/telecom appliance (see e.g., 100, FIG. 1) that is exposed to a (cold-side) entering airflow (see e.g., 118A, FIG. 1) foremost and prior to a computer processor (see e.g., 112, FIG. 1) of said edge/telecom appliance.

In one or many embodiment(s) described herein, the network interface card (200) includes a computer processor (202), one or more small form-factor (SFP) ports (204A, 204B), a bracket apparatus (206), an actuator (214), and an actuator controller (216). Each of these network interface card (200) subcomponents is described below.

In one or many embodiment(s) described herein, the computer processor (202) represents an integrated circuit configured to process computer readable instructions. Said computer readable instructions may govern a behavior, or implement any specified functionalities, of the network interface card (200). Further, said computer processor (202), for example, may encompass one or more cores or micro-cores of an application-specific integrated circuit (ASIC), a field programmable gate array (FPGA), or a microcontroller.

In one or many embodiment(s) described herein, any SFP port (204A, 204B) represents a receptacle designed to a receive a SFP transceiver (also referred to a SFP module) (not shown). Any SFP port (204A, 204B) provides or includes either fiber-optic or copper links, which mate with counter-part fiber-optic or copper links, respectively, of the received SFP transceiver. Further, any SFP port (204A, 204B) enables high-speed telecommunication and/or data communications between their host system (e.g., an edge/telecom appliance) via the network interface card (200) and any number of other systems over one or more networks.

In one or many embodiment(s) described herein, the bracket apparatus (206) represents an assembly of subcomponents collectively configured for ambient temperature regulation of the network interface card (200). To that extent, the bracket apparatus (206) includes an outer bracket (208), an inner bracket (210), and a (miniature) spring (212). In some configurations, the bracket apparatus (206) may further include the actuator (214), which may be mounted onto an inner surface (not shown) of the outer bracket (208). Each of these bracket apparatus (206) subcomponents is described below.

In one or many embodiment(s) described herein, the outer bracket (208) represents mounting hardware configured to attach and detach (e.g., via one or more mechanical fasteners) to/from any PCB expansion card such as, for example, the network interface card (200). Once attached to the PCB expansion card, the outer bracket (208) enables the vertical mounting (e.g., via one or more mechanical fasteners) of the PCB expansion card to any available expansion slot (i.e., an opening) in a front or back panel of a case/chassis (see e.g., 102, FIG. 1) of the host system (e.g., an edge/telecom appliance). The outer bracket (208), further, may be constructed of steel or aluminum sheet, and is illustrated and described in additional detail below with respect to FIG. 2C.

In one or many embodiment(s) described herein, the inner bracket (210) represents a sliding cover configured to move vertically (e.g., up and down) against and relative to the outer bracket (208). Sliding/movement of the inner bracket (210) may be facilitated by the actuator (214), which may be coupled to the inner bracket (210) using one or more mechanical fasteners (not shown). Similar to the outer bracket (208), the inner bracket (210) may be constructed of steel or aluminum sheet, and is illustrated and described in further detail below with respect to FIG. 2D.

In one or many embodiment(s) described herein, the spring (212) represents a physical (mechanical) device, in the form of an elastic coil, configured to extend and compress. The spring (212) may be affixed, at one end thereof, to an inner/inside surface (not shown) of the outer bracket (208) and affixed, at another end thereof, to an inner/inside surface (not shown) at a bottom end of the inner bracket (210). When the spring (212) is compressed (i.e., in a compressed state), the inner bracket (210) is at its lowest position relative to the outer bracket (208). Inversely, when the spring (212) is extended (i.e., in a taut state), the inner bracket (210) is at its highest position relative to the outer bracket (208).

In one or many embodiment(s) described herein, the actuator (214) represents any physical (electro-mechanical) device configured to produce linear motion. Said linear motion may translate into the downward or upward vertical displacement of the inner bracket (210), in relation to a static position of the outer bracket (208), of the bracket apparatus (206). Said displacements are illustrated and described in further detail below with respect to FIGS. 2E and 2F. The actuator (214), furthermore, may be positioned on a face of the network interface card (200) and adjacent to the bracket apparatus (206) (as illustrated in FIG. 2A), or may be installed on the outer bracket (208) of the bracket apparatus itself (206). By way of an example, the actuator (214) may be implemented using a miniaturized linear actuator, including an electric motor, a set of gears, and a worm gear, which collectively convert rotational motion (from the electric motor) into push or pull linear motion.

In one or many embodiment(s) described herein, the actuator controller (216) represents an integrated circuit configured to control and/or operate the actuator (214). The actuator controller (216) may be incorporated into a portion or area of the network interface card (200) (as illustrated in FIG. 2A) and operatively connects, via electrical conductors, to the actuator (214). The actuator controller (216) is illustrated and described in further detail below with respect to FIG. 2B.

While FIG. 2A shows a configuration of components and/or subcomponents, other network interface card (200) configurations may be used without departing from the scope of the embodiments described herein.

For example, in one or many embodiment(s) described herein, any SFP port (204A, 204B), of/on the network interface card (200), may be replaced with another port type. Examples of said replacement port type may include, but are not limited to: a quad SFP (QSFP) port; an octal SFP (OSFP) port; a SFP double density (SFP-DD) port; a QSFP double density (QSFP-DD) port; and a baseband transmission, twisted pair cable (BASE-T) registered jack (RJ)-45 port. Each of the aforementioned replacement port examples may subsequently be configured to receive a corresponding, compatible transceiver.

FIG. 2B shows an actuator controller in accordance with one or more embodiments described herein. The actuator controller (216) includes a temperature switch (218), a super capacitor (220), and a power regulator (222). Each of these actuator controller (216) subcomponents is described below.

In one or many embodiment(s) described herein, the temperature switch (218) represents a physical (electro-mechanical) device configured to open and close a conductive path based on temperature. Said temperature may encompass an ambient temperature surrounding (e.g., in the immediate proximity of) the network interface card (see e.g., 200, FIG. 2A) whereon the actuator controller (216) resides. The temperature switch (218), more specifically, operates (thereby opening and closing its electric contacts) based on a sensed temperature in relation to a threshold temperature. Said sensed temperature refers to the actual ambient temperature of the network interface card (measured by a sensing element (not shown) of the temperature switch (218)), whereas said threshold temperature refers to a settable temperature against which the sensed temperature is compared, leading to the opening or closing of said electric contacts.

In one or more embodiment(s) described herein, said threshold temperature would be set to zero degrees (0°) Celsius (i.e., the temperature at which water freezes, as well as at which network interface cards are often rated). Accordingly, the temperature switch (218) opens the conductive path when the sensed temperature equals or exceeds the threshold temperature and, alternatively, closes the conductive path when the sensed temperature falls below the threshold temperature. In opening the conductive path, the temperature switch (218) severs power to, and thus deactivates, the actuator (214). On the other hand, in closing the conductive path, the temperature switch (218) connects power to, and thus activates, the actuator (214).

In one or many embodiment(s) described herein, the super capacitor (220) represents a physical (energy storage) device capable of undergoing frequent charge and discharge cycles at high current and short duration. As positioned in the actuator controller (216), the super capacitor (220) functions by: (a) storing electrical power, at a regulated voltage produced by the power regulator (222), when power supplied by a network interface card power source (224) is present; and (b) releases any stored electrical power when said power, supplied by the network interface card power source (224) is absent. The super capacitor (220), therefore, provides temporary power to operate the actuator (214) during events when the network interface card power source (224) is unavailable (e.g., when a host edge/telecom appliance (see e.g., 100, FIG. 1) experiences a power disturbance or failure).

In one or many embodiment(s) described herein, the power regulator (also referred to as a voltage regulator) (222) represents a physical (electrical) device configured to maintain and output a specified, constant voltage supply irrespective of the input voltage or any load conditions. The power regulator (222) thus converts a higher input voltage of the network interface card power supply (224) (e.g., 12V) to a fixed, lower output voltage (e.g., 5V, 3.3V, etc.) for which the actuator (214), the temperature switch (218), and the super capacitor (220) may all be rated.

While FIG. 2B shows a configuration of components and/or subcomponents, other actuator controller (216) configurations may be used without departing from the scope of the embodiments described herein.

FIG. 2C shows an outer bracket in accordance with one or more embodiments described herein. The outer bracket (208) includes multiple outer bracket vents (226) and one or more outer bracket port holes (228). Each of these outer bracket (208) subcomponents is described below.

In one or many embodiment(s) described herein, any outer bracket vent (226) represents an opening through which air may pass through the outer bracket (208). Said air, such as the (cold-side) entering airflow (see e.g., 118A, FIG. 1), may pass through to cool any internal components, including the network interface card, of the edge/telecom appliance if no other barrier(s) (e.g., the inner bracket) impede said air from entry.

In one or many embodiment(s) described herein, any outer bracket port hole (228) represents an opening through which a SFP port (see e.g., 204A/B, FIG. 2A) (or a cage assembly (not shown) thereof), of the network interface card, may pass or be accommodated.

FIG. 2D shows an inner bracket in accordance with one or more embodiments described herein. The inner bracket (210) includes multiple inner bracket vents (230) and one or more inner bracket port holes (232). Each of these inner bracket (210) subcomponents is described below.

In one or many embodiment(s) described herein, any inner bracket vent (230) represents an opening through which air may pass through the inner bracket (210). Said air, such as the (cold-side) entering airflow (see e.g., 118A, FIG. 1), may pass through to cool any internal components, including the network interface card, of the edge/telecom appliance without restriction. The dimensions of any inner bracket vent (230) matches the dimensions of any outer bracket vent (see e.g., 226, FIG. 2C) of the outer bracket.

In one or many embodiment(s) described herein, any inner bracket port hole (232) represents an opening through which a SFP port (see e.g., 204A/B, FIG. 2A) (or a cage assembly (not shown) thereof), of the network interface card, may pass or be accommodated. Because the inner bracket (210) is designed to move up or down, in relation to the (static) outer bracket (see e.g., 208, FIG. 2C), any inner bracket port hole (232) thereof is larger than any outer bracket port hole (see e.g., 228, FIG. 2C) of said outer bracket, thereby enabling any inner bracket port hole (232) to accommodate a SFP port irrespective of which position the inner bracket (210) is relative to the outer bracket.

FIG. 2E shows an open-vents configuration of an assembled bracket apparatus in accordance with one or more embodiments described herein. There are two views illustrated in FIG. 2E: the left diagram portrays an inside appliance view, whereas the right diagram portrays an outside appliance view, of the (assembled) bracket apparatus (206A) in its open-vents configuration. The inside appliance view is of the perspective from inside the edge/telecom appliance looking out, while the outside appliance view is of the perspective from outside the edge/telecom appliance looking in. Accordingly, the inside appliance view exposes any inner/inside surface(s), whereas the outside appliance view alternatively exposes any outer/outside surface(s), of the outer bracket (208) and/or inner bracket (210) of the bracket apparatus (206A).

In one or many embodiment(s) described herein, in the open-vents configuration, the inner bracket (210) is positioned (relative to the outer bracket (208)) such that the inner bracket vents (see e.g., 230, FIG. 2D) of the former align with the outer bracket vents (see e.g., 226, FIG. 2C) of the latter. When aligned, air, such as the (cold-side) entering airflow (see e.g., 118A, FIG. 1), is permitted to pass through both the outer and inner brackets (208, 210) to cool any internal components, including the network interface card, of the edge/telecom appliance.

Further, in one or many embodiment(s) described herein, in the open-vents configuration, the spring (212A), affixed at one end to the inside surface of the outer bracket (208) and at another end to the inside surface of the inner bracket (210), remains in or transitions to a compressed state. Moreover, if the bracket apparatus (206A) had been in its closed-vents configuration (see e.g., 206B, FIG. 2F) prior to being in the open-vents configuration, then a downward vertical displacement of the inner bracket (210), relative to the (static) outer bracket (208), would transpire as a result of a deactivated actuator (see e.g., 214, FIG. 2A).

In one or many embodiment(s) described herein, in order to facilitate said downward vertical displacement of the inner bracket (210), the inside surface of the outer bracket (208) may include a rail or guide (not shown) on each side and a height thereof. Alternatively, a pair of miniature rivets may be used to bind the outer and inner brackets (208, 210) yet allow movement of the inner bracket (210). Particularly, the miniature rivets may be disposed near a left and right side edge of the inner bracket (210), where the inner bracket (210) may include vertical cutouts or lanes aligned, respectively, with the positions of the miniature rivets. The inner bracket (210), subsequently, may slide vertically downward (i.e., downward vertical displacement) within a defined range of the vertical cutouts/lanes.

FIG. 2F shows a closed-vents configuration of an assembled bracket apparatus in accordance with one or more embodiments described herein. There are two views illustrated in FIG. 2F: the left diagram portrays an inside appliance view, whereas the right diagram portrays an outside appliance view, of the (assembled) bracket apparatus (206B) in its closed-vents configuration. The inside appliance view is of the perspective from inside the edge/telecom appliance looking out, while the outside appliance view is of the perspective from outside the edge/telecom appliance looking in. Accordingly, the inside appliance view exposes any inner/inside surface(s), whereas the outside appliance view alternatively exposes any outer/outside surface(s), of the outer bracket (208) and/or inner bracket (210) of the bracket apparatus (206B).

In one or many embodiment(s) described herein, in the closed-vents configuration, the inner bracket (210) is positioned (relative to the outer bracket (208)) such that the inner bracket vents (see e.g., 230, FIG. 2D) of the former misalign with the outer bracket vents (see e.g., 226, FIG. 2C) of the latter. When misaligned, air, such as the (cold-side) entering airflow (see e.g., 118A, FIG. 1), is permitted to pass through the outer bracket (208), however, is impeded from passing through the inner bracket (210), thereby preventing the network interface card, of the edge/telecom appliance, from being exposed to any cooling below its rated operating temperature.

Further, in one or many embodiment(s) described herein, in the closed-vents configuration, the spring (212B), affixed at one end to the inside surface of the outer bracket (208) and at another end to the inside surface of the inner bracket (210), remains in or transitions to a taut state. Moreover, if the bracket apparatus (206B) had been in its open-vents configuration (see e.g., 206A, FIG. 2E) prior to being in the closed-vents configuration, then an upward vertical displacement of the inner bracket (210), relative to the (static) outer bracket (208), would need to transpire as a result of an activated actuator (see e.g., 214, FIG. 2A).

In one or many embodiment(s) described herein, in order to facilitate said upward vertical displacement of the inner bracket (210), the inside surface of the outer bracket (208) may include a rail or guide (not shown) on each side and a height thereof. Alternatively, a pair of miniature rivets may be used to bind the outer and inner brackets (208, 210) yet allow movement of the inner bracket (210). Particularly, the miniature rivets may be disposed near a left and right side edge of the inner bracket (210), where the inner bracket (210) may include vertical cutouts or lanes aligned, respectively, with the positions of the miniature rivets. The inner bracket (210), subsequently, may slide vertically upward (i.e., upward vertical displacement) within a defined range of the vertical cutouts/lanes.

FIG. 3 shows a flowchart outlining a method for ambient temperature regulation of a network interface card in accordance with one or more embodiments described herein. The various steps outlined below may be performed by the actuator controller (see e.g., FIGS. 2A & 2B). Further, while the various steps in the flowchart are presented and described sequentially, one of ordinary skill will appreciate that some or all steps may be executed in different orders, may be combined or omitted, and some or all steps may be executed in parallel.

Turning to FIG. 3, in Step 300, an ambient temperature, of a network interface card. is measured. In one or many embodiment(s) described herein, said ambient temperature refers to an actual temperature of any air surrounding (or in the immediate vicinity) of the network interface card. Further, measurement of the ambient temperature may be performed by a sensing element of a temperature switch (see e.g., 218, FIG. 2B) of the actuator controller incorporated into the network interface card. Additionally, or alternatively, measurement of the ambient temperature may be performed by the computer processor (see e.g., 202, FIG. 2A) on/of the network interface card, which, in turn, would report said measurement to the actuator controller.

In Step 302, a determination is made as to whether the ambient temperature (measured in Step 300) is greater than or equal to a threshold temperature of zero degrees (0°) Celsius. In one or many embodiment(s) described herein, if it is determined that the ambient temperature equals or exceeds said threshold temperature, then the method proceeds to Step 304. On the other hand, in one or many other embodiment(s) described herein, if it is alternatively determined that the ambient temperature falls below (i.e., is less than) said threshold temperature, then the method alternatively proceeds to Step 306.

In Step 304, following the determination (made in Step 302) that the ambient temperature (measured in Step 300) equals or exceeds the threshold temperature of zero degrees (0°) Celsius, a conductive path, of the temperature switch (see e.g., 218, FIG. 2B) of the actuator controller, remains in or transitions to an open-state. In one or many embodiment(s) described herein, said conductive path (when in the open-state) subsequently severs power to, and thus deactivates, the actuator (see e.g., 214, FIGS. 2A & 2B). As a result of the actuator being deactivated, the bracket apparatus remains in or transitions to an open-vents configuration (see e.g., 206A, FIG. 2E). In order for the bracket apparatus to transition to the open-vents configuration, a downward vertical displacement of the inner bracket, in relation to the (static) outer bracket, of the bracket apparatus transpires. Further, while in said open-vents configuration, the inner bracket vents (of the inner bracket) are aligned with the outer bracket vents (of the outer bracket), thereby enabling exposure of the network interface card to any (cold-side) entering airflow (see e.g., 118A, FIG. 1) (originating from outside the edge/telecom appliance).

Hereinafter, the method proceeds (back) to Step 300, where the ambient temperature, of the network interface card, is measured again.

In Step 306, following the alternate determination (made in Step 302) that the ambient temperature (measured in Step 300) falls below the threshold temperature of zero degrees (0°) Celsius, a conductive path, of the temperature switch (see e.g., 218, FIG. 2B) of the actuator controller, remains in or transitions to a closed-state. In one or many embodiment(s) described herein, said conductive path (when in the closed-state) subsequently connects power to, and thus activates, the actuator (see e.g., 214, FIGS. 2A & 2B). As a result of the actuator being activated, the bracket apparatus remains in or transitions to a closed-vents configuration (see e.g., 206B, FIG. 2F). In order for the bracket apparatus to transition to the closed-vents configuration, an upward vertical displacement of the inner bracket, in relation to the (static) outer bracket, of the bracket apparatus transpires. Further, while in said closed-vents configuration, the inner bracket vents (of the inner bracket) are misaligned with the outer bracket vents (of the outer bracket), thereby preventing exposure of the network interface card from any (cold-side) entering airflow (see e.g., 118A, FIG. 1) (originating from outside the edge/telecom appliance).

Hereinafter, the method proceeds (back) to Step 300, where the ambient temperature, of the network interface card, is measured again.

While the embodiments described herein have been disclosed with respect to a limited number of embodiments, those skilled in the art, having benefit of this disclosure, will appreciate that other embodiments can be devised which do not depart from the scope of the embodiments described herein. Accordingly, the scope of the embodiments described herein should be limited only by the attached claims.

What is claimed is:

1. A bracket apparatus for ambient temperature regulation of network interface cards, comprising:
a static outer bracket, comprising:
a plurality of outer bracket vents; and
a moveable inner bracket capable of sliding vertically against the static outer bracket, and comprising:
a plurality of inner bracket vents, which:
permits a passage of cold-side airflow when aligned with the plurality of outer bracket vents, and
impedes the passage of the cold-side airflow when misaligned with the plurality of outer bracket vents.

2. The bracket apparatus of claim 1, further comprising:
an actuator coupled to the moveable inner bracket, and configured:
when activated, to execute an upward vertical displacement of the moveable inner bracket; and
when deactivated, to execute a downward vertical displacement of the moveable inner bracket.

3. The bracket apparatus of claim 2, wherein executing the upward vertical displacement of the moveable inner bracket results in a misalignment of the plurality of inner bracket vents with the plurality of outer bracket vents.

4. The bracket apparatus of claim 2, wherein executing the downward vertical displacement of the moveable inner bracket results in an alignment of the plurality of inner bracket vents with the plurality of outer bracket vents.

5. The bracket apparatus of claim 2, further comprising:
an actuator controller operatively connected to the actuator, and comprising:
a temperature switch configured:
when a measured ambient temperature falls below a threshold temperature, to close a conductive path resulting in an activation of the actuator; and
when the measured ambient temperature equals or exceeds the threshold temperature, to open the conductive path resulting in a deactivation of the actuator.

6. The bracket apparatus of claim 5, wherein the threshold temperature is zero degrees Celsius (0° C.).

7. The bracket apparatus of claim 5, wherein the actuator controller further comprises:
a super capacitor disposed between the temperature switch and a power source, and configured:
when the power source is available and the temperature switch is open, to store at least a portion of power, supplied by the power source, as stored power; and
when the power source is unavailable and the temperature switch is closed, to release the stored power.

8. The bracket apparatus of claim 1, further comprising:
a spring affixed:
at one end, to a bottom of the movable inner bracket; and
at another end, to an inside surface of a bottom portion of the static outer bracket.

9. A network interface card, comprising:
a computer processor;
at least one small form-factor pluggable (SFP) port operatively connected to the computer processor; and
a bracket apparatus fitted to, and for ambient temperature regulation of, the network interface card, the bracket apparatus comprising:
a static outer bracket, comprising:
a plurality of outer bracket vents; and
a moveable inner bracket capable of sliding vertically against the static outer bracket, and comprising:
a plurality of inner bracket vents, which:
permits a passage of cold-side airflow when aligned with the plurality of outer bracket vents, and
impedes the passage of the cold-side airflow when misaligned with the plurality of outer bracket vents.

10. The network interface card of claim 9, wherein the bracket apparatus further comprises:
an actuator coupled to the moveable inner bracket, and configured:
when activated, to execute an upward vertical displacement of the moveable inner bracket; and
when deactivated, to execute a downward vertical displacement of the moveable inner bracket.

11. The network interface card of claim 10, wherein the actuator resides on the network interface card and is positioned adjacent to a top portion of the bracket apparatus.

12. The network interface card of claim 10, wherein executing the upward vertical displacement of the moveable inner bracket results in a misalignment of the plurality of inner bracket vents with the plurality of outer bracket vents.

13. The network interface card of claim 10, wherein executing the downward vertical displacement of the moveable inner bracket results in an alignment of the plurality of inner bracket vents with the plurality of outer bracket vents.

14. The network interface card of claim 10, further comprising:
an actuator controller operatively connected to the actuator, and comprising:
a temperature switch configured:
when a measured ambient temperature falls below a threshold temperature, to close a conductive path resulting in an activation of the actuator; and
when the measured ambient temperature equals or exceeds the threshold temperature, to open the conductive path resulting in a deactivation of the actuator.

15. The network interface card of claim 14, wherein the threshold temperature is zero degrees Celsius (0° C.).

16. The network interface card of claim 14, wherein the actuator controller further comprises:
a super capacitor disposed between the temperature switch and a power source of the network interface card, and configured:
when the power source is available and the temperature switch is open, to store at least a portion of power, supplied by the power source, as stored power; and
when the power source is unavailable and the temperature switch is closed, to release the stored power.

17. A computing system, comprising:
a chassis formed from multiple panels fastened together, the multiple panels comprising a panel exposed to a cold-side airflow, and the chassis enclosing:
a motherboard;
a computer processor incorporated into the motherboard; and
a network interface card operatively connected to the computer processor, and comprising:
a second computer processor;
at least one small form-factor pluggable (SFP) port operatively connected to the second computer processor; and
a bracket apparatus fitted to, and for ambient temperature regulation of, the network interface card, the bracket apparatus comprising:
a static outer bracket, comprising:
a plurality of outer bracket vents; and
a moveable inner bracket capable of sliding vertically against the static outer bracket, and comprising:
a plurality of inner bracket vents, which:
permits a passage of the cold-side airflow when aligned with the plurality of outer bracket vents, and
impedes the passage of the cold-side airflow when misaligned with the plurality of outer bracket vents.

18. The computing system of claim 17, wherein the network interface card is mounted vertically on the motherboard and at the panel exposed to the cold-side airflow, and wherein the network interface card is exposed to the cold-side airflow prior to the computer processor.

19. The computing system of claim 17, wherein the network interface card operatively connects to the computer processor using a peripheral component interconnect express (PCIe) interface.

20. The computing system of claim 17, wherein the computing system is an edge appliance or a telecom appliance.
